(19) United States
(12) Patent Application Publication
(10) Pub. No.: US 2026/0082578 A1
(43) Pub. Date: Mar. 19, 2026

(54) SEMICONDUCTOR DEVICE, ELECTRONIC APPARATUS INCLUDING THE SEMICONDUCTOR DEVICE, AND METHOD OF MANUFACTURING THE SEMICONDUCTOR DEVICE

(71) Applicant: Samsung Electronics Co., Ltd., Suwon-si (KR)

(72) Inventors: Donghoon KIM, Suwon-si (KR); Seunggeol NAM, Suwon-si (KR); Sijung YOO, Suwon-si (KR); Dukhyun CHOE, Suwon-si (KR)

(73) Assignee: Samsung Electronics Co., Ltd., Suwon-si (KR)

(21) Appl. No.: 19/053,895

(22) Filed: Feb. 14, 2025

(30) Foreign Application Priority Data
Sep. 13, 2024 (KR) 10-2024-0126152

(51) Int. Cl. H10B 51/30; G06N 3/063; H10B 51/20

(52) U.S. Cl. CPC H10B 51/30; G06N 3/063; H10B 51/20

(57) ABSTRACT

Provided are a semiconductor device, an electronic apparatus including the semiconductor device, and a method of manufacturing the semiconductor device. The semiconductor device includes a channel layer, a ferroelectric layer on the channel layer, and a gate electrode on the ferroelectric layer, wherein the ferroelectric layer includes an interface region, the interface region being a local region of the ferroelectric layer from an interface between the ferroelectric layer and the channel layer to a certain distance, the interface region includes a first material and a second material different from the first material, the first material includes at least one of Mo, TiN, W, or ITO, and the second material includes at least one of Al, Ti, or Ta.

### CROSS-REFERENCE TO RELATED APPLICATION

This application is based on and claims priority under 35 U.S.C. § 119 to Korean Patent Application No. 10-2024-0126152, filed on Sep. 13, 2024, in the Korean Intellectual Property Office, the disclosure of which is incorporated by reference herein in its entirety.

### BACKGROUND

### 1. Field

The present disclosure relates to semiconductor devices including ferroelectrics, electronic apparatuses including the semiconductor device, and/or methods of manufacturing the semiconductor device.

### 2. Description of the Related Art

Ferroelectrics are materials that have ferroelectricity in which internal electric dipole moments are aligned to maintain spontaneous polarization even when no electric field is applied from the outside. The polarization remains semi-permanently within the ferroelectrics even when a certain voltage is applied to the ferroelectrics and the voltage is returned to 0 V. Research has been conducted on application of these ferroelectric characteristics to logic devices or memory devices. For example, in the case of a ferroelectric field-effect transistor using a ferroelectric, the threshold voltage of the field-effect transistor may vary according to the direction and strength of polarization within the ferroelectric. A ferroelectric field-effect transistor is a semiconductor device that implements memory characteristics by controlling the threshold voltage thereof according to the direction of polarization of a ferroelectric by using a ferroelectric layer as a gate insulating film, which has relatively low operating voltage and/or relatively fast programming speed.

### SUMMARY

Provided are semiconductor devices including a ferroelectric layer.

Provided are electronic apparatuses including a semiconductor device including a ferroelectric layer.

Provided are methods of manufacturing a semiconductor device including a ferroelectric layer.

Additional aspects will be set forth in part in the description which follows and, in part, will be apparent from the description, or may be learned by practice of the presented example embodiments of the disclosure.

According to an aspect of an example embodiment, a semiconductor device includes a channel layer including an oxide semiconductor, a ferroelectric layer on the channel layer, and a gate electrode on the ferroelectric layer, wherein the ferroelectric layer includes an interface region, the interface region being a local region of the ferroelectric layer from an interface between the ferroelectric layer and the channel layer to a distance of 15 % or less of a thickness of the ferroelectric layer, the interface region includes a first material, a second material, and oxygen, the first material includes at least one of Mo, TiN, W, or ITO, and the second material includes at least one of Al, Ti, or Ta.

A peak of a content profile of the second material in the interface region is shown may be within a distance range of 15 % or less of the thickness of the ferroelectric layer from the interface between the channel layer and the ferroelectric layer.

A content peak of the second material may be greater than 0 and 25 at % or less.

A content peak of the first material may be greater than 0 and 0.5 at % or less.

A content ratio of the second material to the first material in the interface region may be about 1 or more and about 200 or less.

The first material and the second material may be dispersed in the interface region.

The channel layer, the ferroelectric layer, and the gate electrode may be arranged in a concentric shape, the ferroelectric layer may include the interface region at a region adjacent to the channel layer, and the gate electrode may surround the ferroelectric layer.

The gate electrode may include a plurality of gate electrodes, the plurality of gate electrodes may be arranged to be spaced apart from each other in a first direction, and a spacer may be arranged between each pair of the plurality of gate electrodes.

According to an aspect of another example embodiment, an electronic apparatus includes an array of a plurality of synaptic elements two-dimensionally arranged, wherein any one or more of the plurality of synaptic elements include an access transistor and a ferroelectric field-effect transistor, the ferroelectric field-effect transistor includes a channel layer including an oxide semiconductor, a ferroelectric layer on the channel layer, and a gate electrode on the ferroelectric layer, the ferroelectric layer includes an interface region, the interface region being a local region of the ferroelectric layer from an interface between the ferroelectric layer and the channel layer to a distance of 15 % or less of a thickness of the ferroelectric layer, the interface region includes a first material, a second material, and oxygen, the first material includes at least one of Mo, TiN, W, or ITO, and the second material includes at least one of Al, Ti, or Ta.

According to an aspect of another example embodiment, a method of manufacturing a semiconductor device includes forming a ferroelectric precursor layer, forming a ferroelectric layer by crystallizing the ferroelectric precursor layer by using a first material, forming an interface region within the ferroelectric layer by depositing a second material different from the first material on the ferroelectric layer using an atomic layer deposition method, and forming an oxide semiconductor channel layer on the interface region, wherein the first material includes at least one of Mo, TiN, W, or ITO, and the second material includes at least one of Al, Ti, or Ta.

The interface region may be provided within a distance range of 15 % or less of a thickness of the ferroelectric layer from an interface between the oxide semiconductor channel layer and the ferroelectric layer.

The forming of the ferroelectric layer may include forming a layer of the first material on the ferroelectric precursor layer and crystallizing the ferroelectric precursor layer through heat treatment.

The method of manufacturing the semiconductor device may further include removing the layer of the first material after crystallizing the ferroelectric precursor layer.

At least some of the first material may remain after performing the removing of the layer of the first material.

The depositing of the second material by the atomic layer deposition method may be performed in a range of cycles of 1 or more and 20 or less.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 schematically illustrates a semiconductor device according to an example embodiment;

FIG. 2 shows an element content profile of an interface region of a semiconductor device according to an example embodiment;

FIG. 3 is a diagram to describe a method of manufacturing a semiconductor device, according to an example embodiment;

FIG. 4 shows a semiconductor device of a comparative example;

FIG. 5 shows an I_{D}-V_{G} graph of a comparative example;

FIGS. 6 and 7 show I_{D}-V_{G} graphs of semiconductor devices according to some example embodiments;

FIG. 8 shows an Al concentration in an interface region of a semiconductor device according to an example embodiment;

FIG. 9 shows a Mo concentration in an interface region of a semiconductor device according to an example embodiment;

FIG. 10 shows oxygen intensity profiles of semiconductor devices according to a comparative example and an example embodiment;

FIG. 11 shows an example in which a semiconductor device according to an example embodiment is applied to a ferroelectric field-effect transistor;

FIGS. 12 and 13 are a horizontal cross-sectional view and a vertical cross-sectional view schematically illustrating a structure of a memory cell string of a memory device to which a semiconductor device according to an example embodiment is applied, respectively;

FIG. 14 shows another example of a ferroelectric field-effect transistor to which a semiconductor device according to an example embodiment is applied;

FIG. 15 shows an equivalent circuit of a memory device according to an example embodiment;

FIG. 16 is a schematic circuit diagram of a neural network device according to an example embodiment;

FIG. 17 is a conceptual diagram schematically illustrating a device architecture that may be applied to an electronic apparatus;

FIG. 18 is a block diagram of a memory system according to an example embodiment; and

FIG. 19 is a block diagram of a neuromorphic device according to an example embodiment and an external device connected to the neuromorphic device.

### DETAILED DESCRIPTION

Reference will now be made in detail to some example embodiments which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “one of,” “any one of,” and at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter a semiconductor device, an electronic apparatus including the semiconductor device, and a method of manufacturing the semiconductor device according to various embodiments are described in detail with reference to accompanying drawings. Like reference numerals in the drawings denote like components, and sizes of the components in the drawings may be exaggerated for convenience and clarity of explanation. While such terms as “first,” “second,” etc., may be used to describe various components, such components must not be limited to the above terms. These components are only used to distinguish one component from another.

An expression used in the singular encompasses the expression of the plural, unless it has a clearly different meaning in the context. Also, when a portion ‘includes’ any component, the portion may further include other components, rather than excluding the existence of the other components, unless otherwise described. In addition, sizes and thicknesses of components in the drawings may be exaggerated for clarity of explanation. In addition, when it is described that a certain material layer exists on a substrate or another layer, the material layer may exist in direct contact with the substrate or the other layer, or a third layer may also exist therebetween. Also, materials forming each layer in the following example embodiments are examples, and other materials may be used.

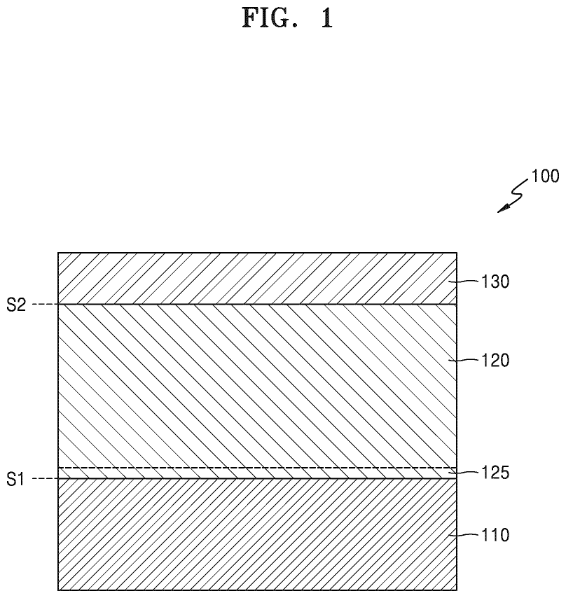

FIG. 1 schematically illustrates a semiconductor device according to an example embodiment.

Referring to FIG. 1, a semiconductor device 100 includes a channel layer 110, a ferroelectric layer 120 provided on the channel layer 110, and a gate electrode 130 on the ferroelectric layer 120. The ferroelectric layer 120 may include a first surface S1 facing the channel layer 110, and a second surface S2 facing the first surface S1. The second surface S2 may be positioned relatively closer to the gate electrode 130 than the channel layer 110. The ferroelectric layer 120 may be arranged to be in direct contact with the channel layer 110. However, the position of the ferroelectric layer 120 is not limited thereto, and another layer may also be inserted between the channel layer 110 and the ferroelectric layer 120. The ferroelectric layer 120 may include an interface region 125 adjacent to an interface between the ferroelectric layer 120 and the channel layer 110.

The channel layer 110 may include an oxide semiconductor material. The oxide semiconductor material may include an oxide of at least one metal from among, for example, indium (In), gallium (Ga), zinc (Zn), tungsten (W), or tin (Sn). For example, the channel layer 110 may include at least one of indium-gallium-zinc oxide (IGZO), indium-zinc oxide (IZO), indium-gallium oxide (IGO), gallium-zinc oxide (GZO), zinc oxide (ZnO), zinc-tin oxide (ZTO), indium tungsten oxide (IWO), In₂O₃, Ga₂O₃, SnO₂, or WO₃. In addition, the channel layer 110 may also include an oxide semiconductor which is further doped with at least one metal from among aluminum (Al), cadmium (Cd), copper (Cu), silicon (Si), zirconium (Zr), magnesium (Mg), or hafnium (Hf). In addition to the materials described above, the channel layer 110 may also include various other oxide semiconductor materials, such as INb₂O₅, TiSrO₃, or the like.

Because an oxide semiconductor material is used as the channel layer 110, the semiconductor device 100 may have relatively low leakage current characteristics in an off state and/or may have a relatively fast operating speed due to relatively high electron mobility of the oxide semiconductor material. In addition, because an insulating interface layer causing unnecessary or undesirable parasitic capacitance is not naturally formed on a surface of the oxide semiconductor material, a memory window, which is a difference between two different threshold voltages of the semiconductor device 100, may increase.

The channel layer 110 may be integrally formed with a semiconductor substrate or may be formed separately from the semiconductor substrate. For example, the channel layer 110 may have a thickness of about 2 nm or more and about 20 nm or less. In some example embodiments, the channel layer 110 may have a thickness of about 10 nm or more and about 20 nm or less. However, the thickness of the channel layer 110 is not limited thereto.

The ferroelectric layer 120 may include a ferroelectric material. A ferroelectric material is a material having ferroelectricity in which internal electric dipole moments are aligned to maintain spontaneous polarization even when no electric field is applied from the outside. A threshold voltage of the semiconductor device 100 may vary according to whether a polarization direction of the ferroelectric layer 120 is, for example, a direction from the gate electrode 130 toward the channel layer 110, or conversely a direction from the channel layer 110 toward the gate electrode 130.

The ferroelectric layer 120 may include a ferroelectric material having at least one structure from among, for example, a fluorite structure, a perovskite structure, or a wurtzite structure. A ferroelectric material in a fluorite structure may include, for example, hafnium oxide (HfO). For example, the ferroelectric material may include hafnium oxide and a dopant. The dopant may include, for example, at least one of Zr, lanthanum (La), Al, Si, or yttrium (Y). In some example embodiments, the ferroelectric layer 120 may include hafnium and zirconium in almost the same element ratio (e.g., Hf_{0.5}Zr_{0.5}O), and may further be doped with at least one element from among La, Al, Si, Y, or gadolinium (Gd) at a ratio of less than 10 at %. The ferroelectric material may include an orthorhombic crystal phase. In addition, a ferroelectric material in a perovskite structure may include lead zirconate titanate (PZT). A ferroelectric material in a wurtzite structure may include, for example, zinc oxide (ZnO) or aluminum nitride (AlN). Such a ferroelectric material in the wurtzite structure may be doped with at least one dopant from among, for example, boron (B) or scandium (Sc). A thickness of the ferroelectric layer 120 may be, for example, about 5 nm or more and about 20 nm or less. In some example embodiments, the thickness of the ferroelectric layer 120 may be about 5 nm or more and about 10 nm or less. However, the thickness of the ferroelectric layer 120 is not limited thereto.

The ferroelectric layer 120 may also further include an antiferroelectric material. For example, the antiferroelectric material may also include zirconium oxide. The zirconium oxide may be doped with at least one element from among, for example, Hf, La, Al, Si, Y, or Gd.

The ferroelectric material has ferroelectricity in which internal electric dipole moments are aligned to maintain spontaneous polarization even when no electric field is applied from the outside, and has switchable polarization. When no electric field is applied to the ferroelectric material, the ferroelectric material has a random polarization direction, but when an electric field is applied, a polarization size of the ferroelectric material increases to have a polarization direction that is the same as a direction of the electric field. The ferroelectric material has a characteristic of maintaining polarization aligned in one direction even when an electric field is generated and then removed. For example, in the case of a ferroelectric field-effect transistor (FeFET) using a ferroelectric material, a threshold voltage of the field-effect transistor may vary according to the direction and strength of polarization within the ferroelectric material. Such a threshold voltage variation characteristic of the FeFET may be used to implement a logic device, a memory device, a neuromorphic array, or the like.

The FeFET has a structure in which SiO₂ used as a gate oxide film in a metal oxide semiconductor field-effect transistor (MOSFET) is replaced with a ferroelectric material. Generally, a FeFET based on a silicon channel has a structure that is vulnerable to reliability due to an interlayer generated between a ferroelectric material and a channel layer. The FeFET based on the silicon channel has a metal-ferroelectric-interlayer dielectric-Si (MFIS) structure. Here, interlayer dielectric includes a native oxide that is naturally formed when a ferroelectric material is deposited on a Si substrate, and the interlayer dielectric causes deterioration of endurance, or the like. Therefore, memory based on an oxide semiconductor channel that does not generate an interlayer dielectric material is widely used.

Ferroelectric memory using an oxide semiconductor may include a metal-ferroelectric-oxide semiconductor (MFS) structure, and the memory may operate by controlling a threshold voltage of the oxide semiconductor according to a polarization direction of a ferroelectric material. A FeFET based on an oxide semiconductor channel does not include an interlayer between a ferroelectric material and a channel layer, thereby reducing or preventing a problem of reliability deterioration due to the interlayer. However, in a FeFET including a channel layer based on an oxide semiconductor, a subthreshold swing thereof increases due to a deterioration problem of an off state. For example, in the case of a FeFET using an IGZO channel layer as an oxide semiconductor, because the channel layer is an n-type channel, threshold voltages of both program (PGM) and erase (ERS) states may tend to be biased in a negative direction due to a characteristic of insufficient role of hole carriers, an off current may increase due to interface characteristics between a ferroelectric layer and an oxide semiconductor channel layer, and a subthreshold swing (SS) value of the erase state may increase. However, in a semiconductor device or FeFET according to an example embodiment, an off current may be reduced and/or SS may be reduced by providing the interface region 125 at an interface between a ferroelectric layer and a channel layer.

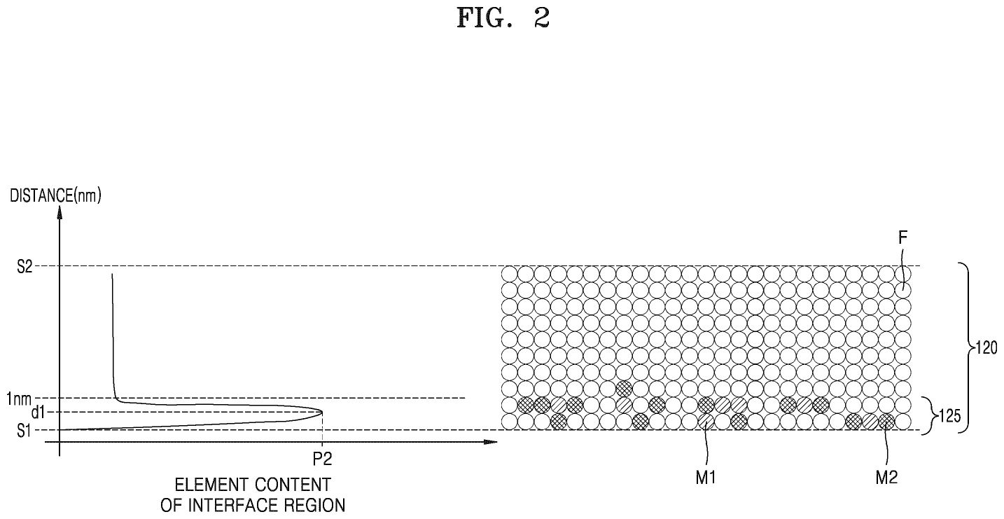

The interface region 125 may be provided in a region adjacent to an interface between the channel layer 110 and the ferroelectric layer 120. The region adjacent to the interface may represent a region of the ferroelectric layer 120 from the interface to a certain distance. FIG. 2 shows the position of the interface region 125.

The interface region 125 may include a first material M1, a second material M2 that is different from the first material M1, and oxygen. The first material M1 may be a conductive material including at least one of Mo, TiN, W, or ITO. The first material M1 may be used to form the ferroelectric layer 120 by crystallizing an amorphous ferroelectric precursor. The second material M2 may include metal having a higher oxidation reactivity than the channel layer 110. The second material M2 may be, for example, metal including at least one of Al, Ti, or Ta. The second material M2 may reduce or prevent deterioration of the interface between the channel layer 110 and the ferroelectric layer 120.

The interface region 125 may have an oxide structure including the first material M1, the second material M2 and oxygen. In the interface region 125, the first material M1 and the second material M2 may be dispersed within the ferroelectric layer 120 instead of existing as a separate layer within the ferroelectric layer 120. For example, when the ferroelectric layer 120 includes a ferroelectric material of hafnium oxide, the interface region 125 may include the first material M1, the second material M2, hafnium, and oxygen. The reference numeral F may represent a ferroelectric material.

The interface region 125 may be a local region of the ferroelectric layer 120, for example, a distance range of 1 nm or less from the interface of the channel layer 110 and the ferroelectric layer 120. The interface region 125 may be defined based on a peak of a content profile of the second material M2. For example, in the interface region 125, a position d1 indicating a peak value P2 of the content profile of the second material M2 may be within a distance range of 1 nm or less, 0.7 nm or less, or 0.5 nm or less from the interface (e.g., the first surface S1) of the channel layer 110 and the ferroelectric layer 120. The interface region 125 may be a local region of the ferroelectric layer 120 from the interface (e.g., the first surface S1) of the channel layer 110 and the ferroelectric layer 120 to a distance of 15 % or less, 10 % or less, or 5 % or less of the thickness of the ferroelectric layer 120.

In the interface region 125, the content of the first material M1 may be greater than 0 at % or 0.1 at % or more and 0.5 at % or less. In the interface region 125, the content of the second material M2 may be greater than 0 and 25 at % or less. In some example embodiments, in the interface region 125, the content of the second material M2 may be greater than 0 and 10 at % or less. In some example embodiments, in the interface region 125, the content of the second material M2 may be greater than 0 and 5 at % or less. In the interface region 125, a ratio M2/M1 of the second material M2 to the first material M1 may be 1 or more, 5 or more, 200 or less, 150 or less, or 100 or less. The presence and content of each material or element in the interface region 125 may be confirmed through a secondary ion mass spectrometry (SIMS) analysis.

In some example embodiments, in the interface region 125, a content peak P1 of the first material M1 may be greater than 0 at % or 0.1 at % or more and 0.5 at % or less. In the interface region 125, a content peak P2 of the second material M2 may be greater than 0 and 25 at % or less. in some example embodiments, in the interface region 125, the content peak P2 of the second material M2 may be greater than 0 and 10 at % or less. in some example embodiments, in the interface region 125, the content peak P2 of the second material M2 may be greater than 0 and 5 at % or less. In the interface region 125, a ratio P2/P1 of the content peak P1 of the first material M1 and the content peak P2 of the second material M2 may be 1 or more, 5 or more, 200 or less, 150 or less, or 100 or less. The content peak of each material or element in the interface region 125 may be confirmed through an atom probe tomography (APT) analysis.

The interface region 125 may reduce deterioration at the interface between the channel layer 110 and the ferroelectric layer 120, thereby reducing SS. For example, when the channel layer 110 includes IGZO, and the ferroelectric layer 120 includes HZO, deterioration in an HZO/IGZO interface occurs due to impurities generated during heat treatment to crystallize HZO, but the interface region 125 may reduce or prevent such interface deterioration.

The gate electrode 130 may have a conductivity of approximately 1 Mohm/square or less. The gate electrode 130 may include at least one selected from a group including metal, metal nitride, metal carbide, polysilicon, and combinations thereof. For example, the metal may include Al, tungsten (W), molybdenum (Mo), titanium (Ti), or tantalum (Ta), a metal nitride film may include a titanium nitride (TiN) film or a tantalum nitride (TaN) film, the metal carbide may be metal carbide doped with (or containing) aluminum or silicon, and some examples thereof may include TiAlC, TaAlC, TiSiC or TaSiC.

The gate electrode 130 may also have a structure in which a plurality of materials are stacked. For example, the gate electrode 130 may have a stacked structure of a metal nitride layer/metal layer, such as TiN/Al or the like, or may have a stacked structure of a metal nitride layer/metal carbide layer/metal layer, such as TiN/TiAlC/W. The gate electrode 130 may include a titanium nitride (TiN) film or molybdenum (Mo), and the above example may be used in various modified forms.

In addition, the gate electrode 130 may also include a two-dimensional conductive material, in addition to the materials stated above. For example, the two-dimensional conductive material may include at least one of graphene, black phosphorus, amorphous boron nitride, two-dimensional hexagonal boron nitride (h-BN), or phosphorene.

The semiconductor device 100 according to an example embodiment may reduce SS and reduce an off current by including the interface region 125 in the ferroelectric layer 120.

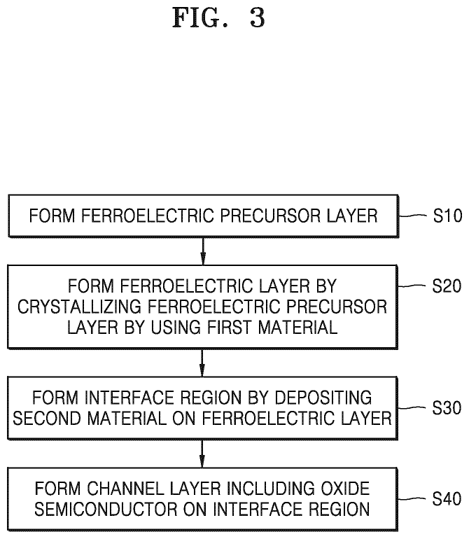

FIG. 3 shows a method of manufacturing a semiconductor device, according to an example embodiment.

Referring to FIG. 3, a ferroelectric precursor layer is formed (S10). The ferroelectric precursor layer may represent an amorphous layer before a ferroelectric material is crystallized. The ferroelectric precursor layer may be formed by a physical vapor deposition method, a chemical vapor deposition method, or an atomic layer deposition method. For example, in the case of forming a ferroelectric layer of Hf_{0.5}Zr_{0.5}O₂, an amorphous Hf_{0.5}Zr_{0.5}O₂ ferroelectric precursor layer may be formed by alternately depositing hafnium oxide and zirconium oxide by using an atomic layer deposition method.

Then, a ferroelectric layer is formed by crystallizing the ferroelectric precursor layer by using a first material (S20). The ferroelectric layer may be formed by forming a layer of the first material on the ferroelectric precursor layer and crystallizing the ferroelectric precursor layer through heat treatment. The first material may include, for example, at least one of Mo, TiN, W, or ITO.

The heat treatment may be performed under a condition in which amorphous hafnium oxide may be crystallized to have an orthorhombic crystal phase. For example, annealing may be performed at a temperature of about 400° C. to about 1100° C., but is not limited thereto. The annealing may be performed for a time period of one nano-second or more, one micro-second or more, 0.001 seconds or more, 0.01 seconds or more, 0.05 seconds or more, 0.1 seconds or more, 0.5 seconds or more, 1 second or more, 3 seconds or more, 5 seconds or more, 10 minutes or less, 5 minutes or less, 1 minute or less, or 30 seconds or less, but is not limited thereto. At this time, a portion of the first material may be dispersed or introduced into the ferroelectric layer.

After the ferroelectric layer is formed, the layer of the first material may be removed. However, the first material may not be completely removed, and a portion of the first material may remain within the ferroelectric layer. The first material may be present within the ferroelectric layer in an amount greater than 0 at % and 0.5 at % or less.

An interface region may be formed by depositing a second material on at least a portion of a region, where the layer of the first material has been removed, in the ferroelectric layer by an atomic layer deposition method (S30). The atomic layer deposition method may be performed within a range of 1 to 20 cycles, 1 to 10 cycles, or 1 to 5 cycles. The atomic layer deposition method may be performed so that the second material is dispersed within the interface region in an amount greater than 0 at % and 25 at % or less, 10 at % or less, or 5 at % or less.

Also, a channel layer including an oxide semiconductor may be formed on the interface region (S40). The channel layer may be formed by a physical vapor deposition method, a chemical vapor deposition method, or an atomic layer deposition method.

In the method of manufacturing a semiconductor device according to an example embodiment, the interface region may be formed in a structure or as a local region of the ferroelectric layer (instead of being a separate thin film region) in which the second material is diffused or dispersed. The second material may include a material having a higher oxidation reactivity than the channel layer. The second material may include, for example, at least one of Al, Ti, or Ta. The first material that remained after the crystallization process may cause interface deterioration by inducing oxygen vacancy. However, in the semiconductor device according to an example embodiment, the second material may reduce or prevent the interface deterioration by passivating the first material, thereby reducing SS. However, when the deposition cycle of the second material exceeds 20 cycles and the second material is deposited as a separate thin film, interface deterioration increases while an oxide film is formed by the second material, and thus, SS may increase, and/or the channel layer may be oxidized to reduce the performance of the semiconductor device.

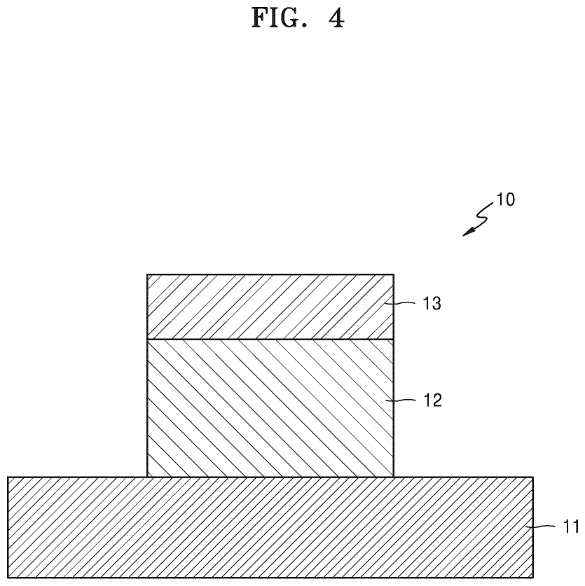

FIG. 4 shows a semiconductor device 10 of a comparative example. The semiconductor device 10 includes an IGZO channel layer 11, an HZO ferroelectric layer 12, and a gate electrode 13. The semiconductor device 10 has a structure in which an interface region substantially does not exist at an interface between the IGZO channel layer 11 and the HZO ferroelectric layer 12.

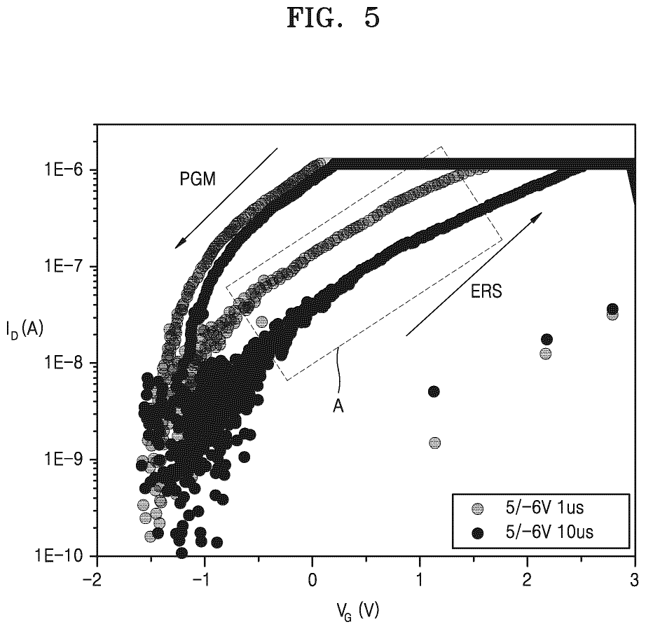

FIG. 5 shows an I_{D}-V_{G} graph for the semiconductor device 10 of the comparative example. The dots in a mesh pattern represent a case where 5/-6 V is applied for 1 μs, and the black dots represent a case where 5/-6 V is applied for 10 μs. In a region A, the reciprocal of a slope of an erase state ERS represents an SS of the semiconductor device 10 of the comparative example.

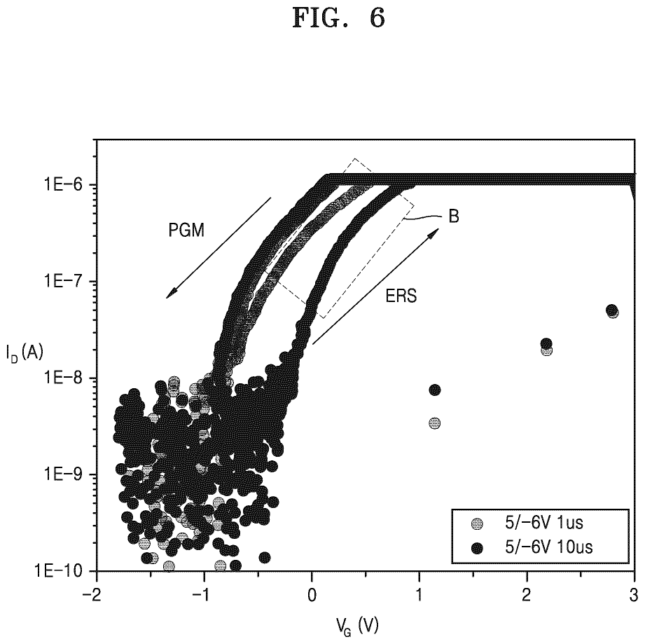

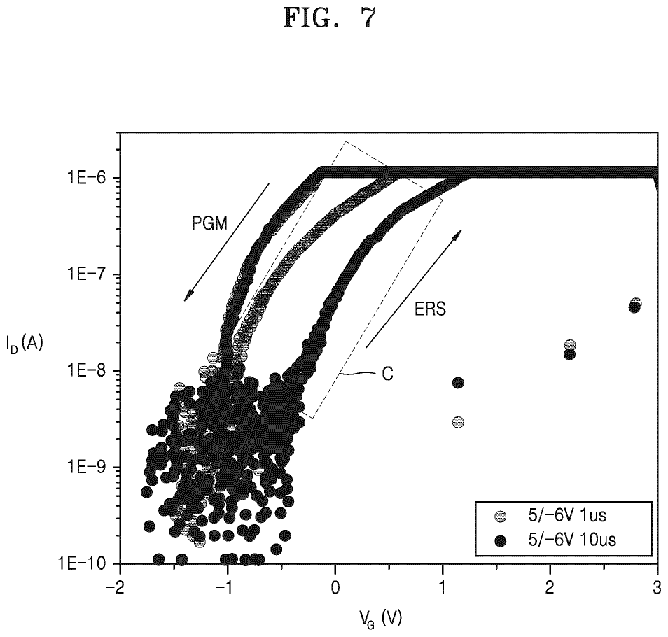

Each of FIGS. 6 and 7 shows an I_{D}-V_{G} graph of the semiconductor device 100 according to an example embodiment. Each semiconductor device includes the IGZO channel layer 110, the HZO ferroelectric layer 120, and the gate electrode 130, and the interface region 125. The interface region 125 is formed by using Mo as a first material and Al as a second material. FIG. 6 shows introduction of the second material (Al) into the interface region through an atomic layer deposition method having three cycles, and FIG. 7 shows introduction of the second material (Al) into the interface region through an atomic layer deposition method having two cycles.

When comparing the region A of FIG. 5, a region B of FIG. 6, and a region C of FIG. 7, slopes of erase states ERS and slopes of program states PGR in the region B and the region C are relatively greater than the slope of the erase state ERS and a slope of the program state PGR in the region A. In other words, the semiconductor device 100 according to an example embodiment has a relatively smaller SS than the semiconductor device 10 of the comparative example. This shows that the interface region 125 of the ferroelectric layer 120 adjacent to the channel layer 110 improves SS by reducing deterioration occurring at the interface with the channel layer 110.

A state in which Hf, Zr, Mo, Al, and O were dispersed in the interface region 125 within the ferroelectric layer 120 was confirmed through energy dispersive X-ray spectroscopy (EDS). The interface region 125 may be provided in a form in which Hf, Zr, Mo, Al, and O are dispersed or diffused in a region within an HZO ferroelectric layer 120 that is adjacent to the channel layer 110, instead of being a separate distinct interlayer. As the interface region 125 is a local region of the ferroelectric layer 120 from the interface between the ferroelectric layer 120 and the channel layer 110 to a certain distance, an increase in SS due to interface deterioration may be prevented or reduced. When the interface region 125 is provided as a separate film instead of being provided in the local region of the ferroelectric layer 120 and the channel layer 110, an SS may increase due to deterioration of the film, and/or durability of the semiconductor device may decrease. Accordingly, an increase in SS may be reduced or prevented by providing the interface region 125 in a local region of the ferroelectric layer 120, instead of providing the interface region 125 as a separate film. The interface region 125 may include a ferroelectric material F in the ferroelectric layer 120 together with the first material M1 and the second material M2 in the region of the ferroelectric layer 120 that is adjacent to the channel layer 110.

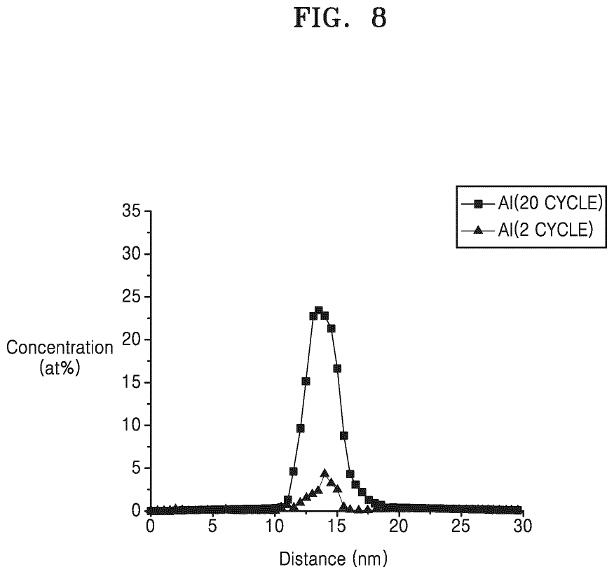

FIG. 8 shows an Al concentration (at %) of the interface region 125 of the semiconductor device 100 according to an example embodiment through an APT analysis. In the disclosure, terms of concentration and content may be interchangeably used. The horizontal axis represents a distance from a lower surface of a channel layer of the semiconductor device 100, and the vertical axis represents an Al concentration. The square dots represent a case where Al was deposited for 20 cycles after annealing a ferroelectric precursor layer, and the triangular dots represent a case where Al was deposited for 2 cycles after annealing the ferroelectric precursor layer. Referring to FIG. 8, a region where the Al concentration shows a peak is shown, and the region may represent the interface region 125. The peak of the Al concentration (or content) may be greater than 0 and 25 at % or less. in some example embodiments, the peak of the Al concentration (or content) may be greater than 0 and 10 at % or less. in some example embodiments, the peak of the Al concentration (or content) may be greater than 0 and 5 at % or less.

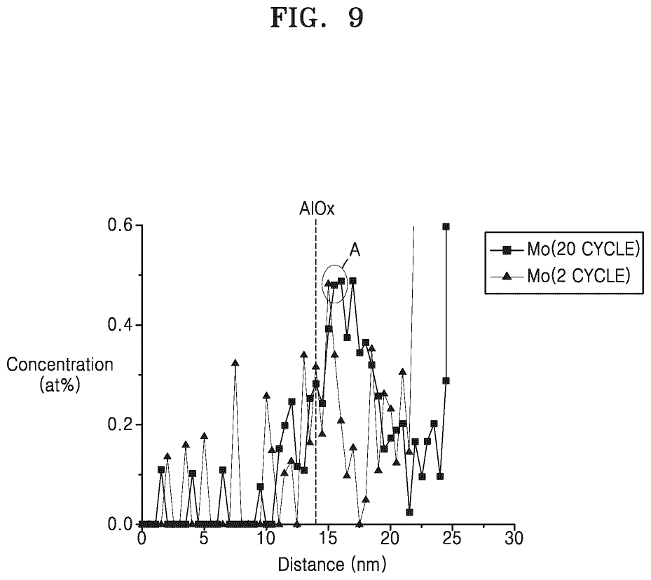

FIG. 9 shows a Mo concentration (at %) of the interface region 125 of the semiconductor device 100 according to an example embodiment through an APT analysis. The horizontal axis represents a distance from a lower surface of a channel layer of the semiconductor device 100, and the vertical axis represents an Mo concentration. The square dots and the triangular dots in FIG. 9 represent the same as those in FIG. 8. In FIG. 9, a region A is a region where the Mo concentration shows a peak. It may be seen that the region where the Mo concentration shows a peak is adjacent to a region AlOx where the Al concentration shows a peak in FIG. 8, and this indicates that Al and Mo are present in the interface region 125 of the semiconductor device 100 according to an example embodiment. Referring to FIG. 9, the peak of the Mo concentration (or content) may be greater than 0 or 0.5 at %.

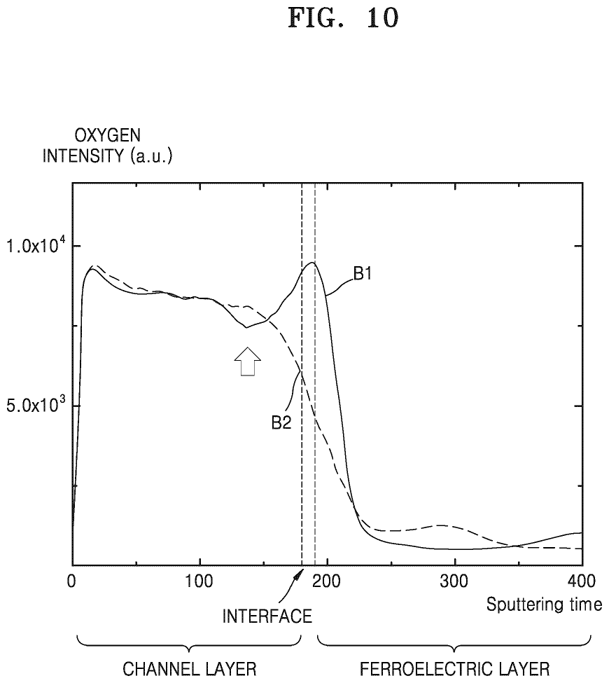

FIG. 10 shows an oxygen profile of a semiconductor device according to an example embodiment through a silicon photomultipliers (SIPMS) analysis. The horizontal axis represents sputtering time, and the vertical axis represents oxygen intensity. FIG. 10 shows results obtained by measuring oxygen intensity of each layer of the semiconductor device while sputtering the semiconductor device. The left side of a portion indicated as interface represents a channel layer region, and the right side thereof represents a ferroelectric layer. The B1 graph shows a comparative example, and the comparative example shows a case in which a Mo layer was formed on an HZO ferroelectric precursor layer and annealed to form an HZO ferroelectric layer, and then the Mo layer was removed to form an IGZO channel layer on the HZO ferroelectric layer without introducing a second material (Al). The B1 graph shows that the oxygen intensity decreases relatively significantly at a portion indicated by the arrow, and the oxygen concentration increases relatively significantly at the interface between the channel layer and the ferroelectric layer. This indicates that, in the comparative example, oxygen in the channel layer flows toward the interface with the ferroelectric layer, inducing an oxygen vacancy in the channel layer. The oxygen vacancy in the channel layer causes interface deterioration of the channel layer.

The B2 graph shows an example embodiment, and the example embodiment shows a case in which an HZO ferroelectric layer was formed by crystallizing an HZO ferroelectric precursor layer by using Mo, Mo was removed and Al was deposited by an atomic layer deposition method to form an interface region within the HZO ferroelectric layer, and then an IGZO channel layer was formed on the interface region. The B2 graph shows that a decrease in oxygen concentration in the channel area region indicated by the arrow is relatively small compared to the comparative example. This indicates that an oxygen vacancy of the channel layer is not induced at the interface region of the semiconductor device according to an example embodiment, and accordingly, interface deterioration of the channel layer may be reduced.

As described above, the semiconductor device according to an example embodiment may reduce SS, increase durability of the semiconductor device, and/or reduce an off current by including an interface region at an interface between a channel layer and a ferroelectric layer. Such a semiconductor device may be applied to a FeFET and a memory device, such as dynamic random-access memory (DRAM) and NAND FLASH, may be installed in an electronic apparatus such as a mobile phone, a television (TV), or the like, and may also be applied to a neuromorphic device.

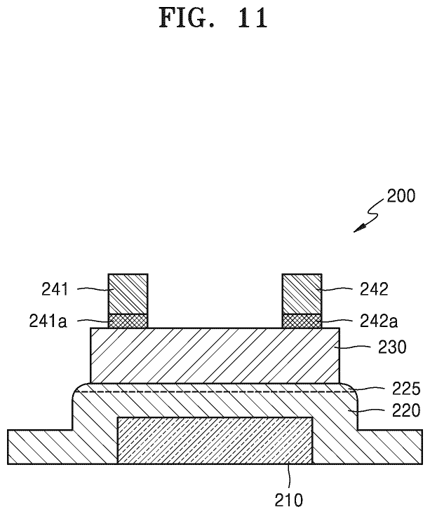

FIG. 11 is a cross-sectional view schematically illustrating an example in which a semiconductor device according to an example embodiment is applied to a FeFET. Referring to FIG. 11, a FeFET 200 may include a gate electrode 210, a ferroelectric layer 220 on an upper portion of the gate electrode 210, a channel layer 230 on an upper portion of the ferroelectric layer 220, a source electrode 241 arranged on an upper portion of the channel layer 230, and a drain electrode 242 arranged on the upper portion of the channel layer 230 and spaced apart from the source electrode 241. The ferroelectric layer 220 may include an interface region 225 at a region adjacent to the channel layer 230. Here, the gate electrode 210, the ferroelectric layer 220, the interface region 225, and the channel layer 230 are substantially the same as the components having the same names as described with reference to FIG. 1, and thus, detailed descriptions thereof are omitted.

The FeFET 200 may also selectively include, as desired, a first contact layer 241a between the source electrode 241 and the channel layer 230, and a second contact layer 242a between the drain electrode 242 and the channel layer 230. The first contact layer 241a and the second contact layer 242a may lower contact resistance between the source electrode 241 and the channel layer 230 and contact resistance between the drain electrode 242 and the channel layer 230, respectively. Each of the first contact layer 241a and the second contact layer 242a may include, for example, indium tin oxide (ITO).

The example embodiments described above may also be applied to a memory device having a vertical NAND (VNAND) structure, which is a three-dimensional (or vertical) NAND.

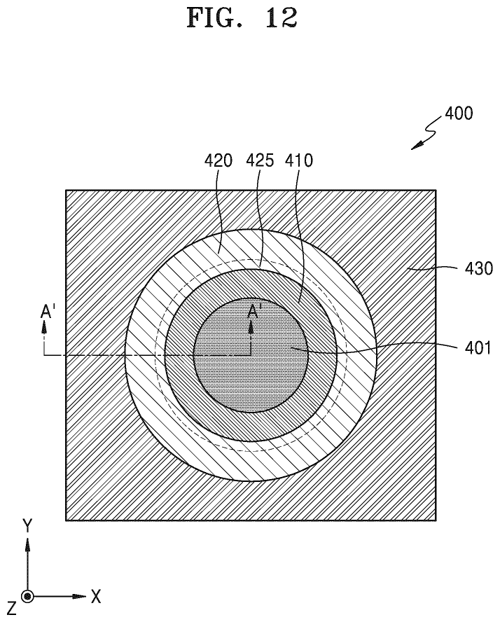

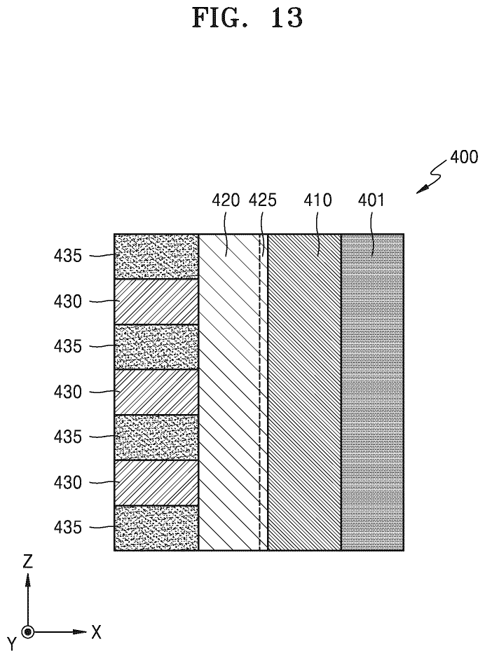

FIGS. 12 and 13 are a horizontal cross-sectional view and a vertical cross-sectional view schematically illustrating a structure of a memory cell string of a memory device according to an example embodiment, respectively. Referring to FIG. 12, a memory cell string of a memory device 400 according to an example embodiment may include a center filler 401, a channel layer 410, a ferroelectric layer 420, which are arranged in a concentric shape on an XY plane, and a gate electrode 430. The channel layer 410 may be arranged to surround the center filler 401, the ferroelectric layer 420 may be arranged to surround the channel layer 410, and the gate electrode 430 may be arranged to surround the ferroelectric layer 420. The ferroelectric layer 420 may include an interface region 425 at a region adjacent to the channel layer 410. The center filler 401 may fill a space on an inner wall side of the channel layer 410 and support the channel layer 410 and the memory device 400. However, the center filler 401 is not an essential component and may be omitted. In this case, a void space may also exist instead of the center filler 401.

FIG. 13 is a schematic cross-sectional view taken along a line A-A′ of FIG. 12 in a first direction (e.g., a Z-axis direction) from the center of the center filler 401 to the gate electrode 430. Referring to FIG. 13, the memory device 400 may include a plurality of gate electrodes 430, and the plurality of gate electrodes 430 may be arranged to be spaced apart from each other in the first direction. Also, a spacer 435 may be arranged between the plurality of gate electrodes 430. That is, the plurality of gate electrodes 430 and a plurality of spacers 435 may be alternately arranged in the first direction. The memory device 400 may include the channel layer 410 continuously extending in the first direction and facing but spaced apart from the plurality of gate electrodes 430 and the plurality of spacers 435 in a second direction (e.g., an X-axis direction) perpendicular to the first direction, and the ferroelectric layer 420 continuously extending in the first direction and arranged between the channel layer 410 and the plurality of gate electrodes 430. The ferroelectric layer 420 may include the interface region 425 provided at a region adjacent to the channel layer 410. In addition, the memory device 400 may further include the center filler 401 on an inner side of the channel layer 410, the center filler 401 continuously extending in the first direction. In other words, the ferroelectric layer 420, the channel layer 410, and the center filler 401 may be sequentially arranged from the plurality of gate electrodes 430 and the plurality of spacers 435 in the second direction. The interface region 425 may be provided in the ferroelectric layer 420 at the interface with the channel layer 410.

Each of the plurality of spacers 435 may include silicon oxide (SiO₂) having insulating properties, but is not limited thereto. The ferroelectric layer 420 may include the same ferroelectric material as the ferroelectric layer 120 described with reference to FIG. 1, and the channel layer 410 may include the same oxide semiconductor material as the channel layer 110 described with reference to FIG. 1. In addition, the interface region 425 may include the same components as the interface region 225 described with reference to FIG. 1.

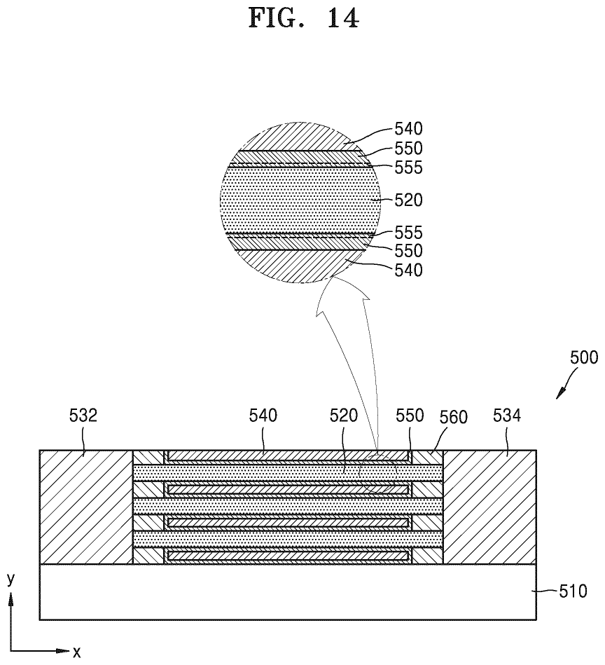

FIG. 14 is a diagram showing a FeFET 500 according to an example embodiment. The FeFET 500 includes a plurality of channel layers 520 arranged on a substrate 510, a source 532 and a drain 534, which are in contact with the channel layers 520, and a plurality of gate electrodes 540 arranged to be spaced apart from the plurality of channel layers 520. The FeFET 500 may be applied to a so-called gate-all-around (GAA) transistor.

The substrate 510 may be an insulating substrate or may be a semiconductor substrate having an insulating layer formed on a surface thereof. The semiconductor substrate may include, for example, Si, Ge, SiGe, or the like. The substrate 510 may be, for example, a silicon substrate having silicon oxide formed on a surface thereof, but is not limited thereto.

The source 532 and the drain 534 may be arranged on the substrate 510 and be spaced apart from each other in a first direction (X direction), and the plurality of channel layers 520 may be arranged between the source 532 and the drain 534 and be spaced apart from each other in a second direction (Y direction).

The plurality of gate electrodes 540 may be arranged to be spaced apart from each channel layer 520, and a ferroelectric layer 550 may be arranged between the gate electrode 540 and the channel layer 520. For example, the ferroelectric layer 550 may be provided to surround at least a portion of the gate electrode 540. For example, the gate electrode 540 and the channel layer 520 may be alternately arranged in the second direction (Y direction), and the ferroelectric layer 550 may surround the gate electrode 540. The ferroelectric layer 550 may provide insulation between the channel layer 520 and the gate electrode 540 and may suppress leakage current. The ferroelectric layer 550 may include an interface region 555 provided at a region adjacent to the channel layer 520.

A contact between each of the channel layer 520 and the source 532 and the drain 534 may have an edge contact form. For example, both ends of the channel layer 520 may be in contact with the source 532 and the drain 534, respectively.

Each of the gate electrode 540 may be spaced apart from the source 532 and the drain 534, and a spacer 560 may be further arranged between the gate electrode 540 and the source 532 and between the gate electrode 540 and the drain 534. Because the source 532, the gate electrode 540, and the drain 534 are arranged in the first direction (X direction), parasitic capacitance may occur between the source 532 and the gate electrode 540 and between the gate electrode 540 and the drain 534. To reduce parasitic capacitance, the spacer 560 may include, for example, a boron nitride film. Because the boron nitride film has a mechanical strength without porosity, the boron nitride film may safely support the channel layer 520 arranged on an upper layer of the spacer 560.

The FeFET 500 may have a multi-bridge form in which the plurality of channel layers 520 are stacked to be spaced apart from each other in a direction away from the substrate 510 and each of the plurality of channel layers 520 has both ends in contact with the source 532 and the drain 534. A channel of the multi-bridge form may reduce a short channel effect and reduce an area occupied by the source/drain, and thus the channel is advantageous for higher integration. In addition, because the channel may maintain a relatively uniform source/drain junction regardless of the position of the channel, the channel may be applied to higher-speed and/or higher-reliability devices.

The FeFET 500 may be applied to, for example, a logic device, a memory device, or the like. When the ferroelectric layer 550 includes the interface region 555, an SS may be reduced, and thus the performance of the FeFET 500 may be improved while reducing the size of the FeFET 500.

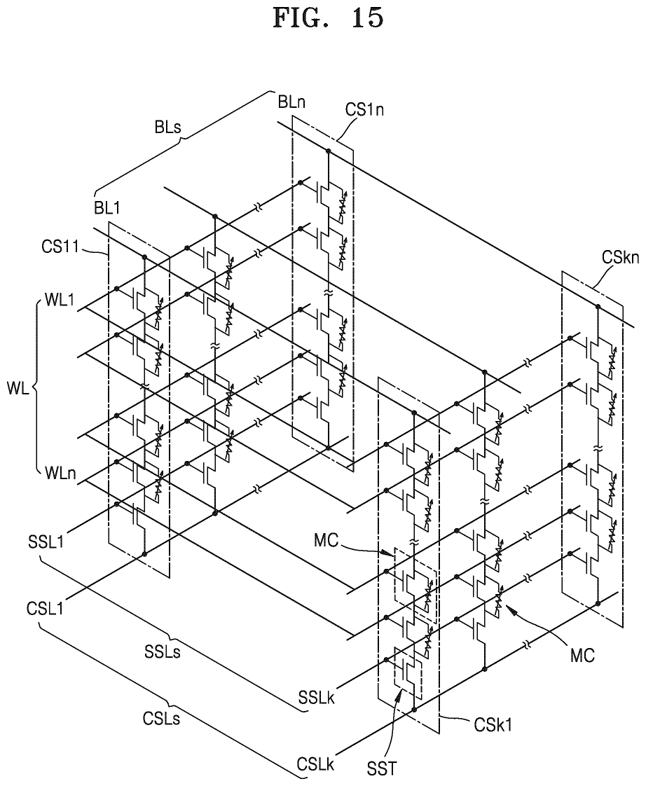

FIG. 15 shows an equivalent circuit of a memory device according to an example embodiment.

Referring to FIG. 15, the memory device may include a plurality of memory cell strings CS11 to CSkn. The plurality of memory cell strings CS11 to CSkn may be two-dimensionally arranged in a row direction and a column direction to form rows and columns. Each of the plurality of memory cell strings CS11 to CSkn may include a plurality of memory cells MC and a plurality of string selection transistors SST. The plurality of memory cells MC and the plurality of string selection transistors SST of each of the plurality of memory cell strings CS11 to CSkn may be stacked in a height direction. The plurality of memory cells MC of each of the plurality of memory cell strings CS11 to CSkn may correspond to a circuit in which transistors and resistors are connected in parallel. For example, each of the plurality of memory cell strings CS11 to CSkn may be the memory cell string as shown in FIGS. 12 and 13.

The rows of the plurality of memory cell strings CS11 to CSkn may be connected to different string selection lines SSL1 to SSLk, respectively. For example, the string selection transistors SST of memory cell strings CS11 to CS1n are commonly connected to the string selection line SSL1. The string selection transistors SST of memory cell strings CSk1 to CSkn are commonly connected to the string selection line SSLk.

In addition, the columns of the plurality of memory cell strings CS11 to CSkn are connected to different bit lines BL1 to BLn, respectively. For example, the memory cells MC and the string selection transistors SST of the memory cell strings CS11 to Csk1 may be commonly connected to the bit line BL1, and the memory cells MC and the string selection transistors SST of the memory cell strings CS1n to CSkn may be commonly connected to the bit line BLn.

In addition, the rows of the plurality of memory cell strings CS11 to CSkn may be connected to different common source lines CSL1 to CSLk, respectively. For example, the string selection transistors SST of the plurality of memory cell strings CS11 to CS1n may be commonly connected to the common source line CSL1, and the string selection transistors SST of the plurality of memory cell strings CSk1 to CSkn may be commonly connected to the common source line CSLk.

The memory cells MC positioned at the same height from a substrate (or the string selection transistors SST) may be commonly connected to one word line WL, and the memory cells MC positioned at different heights may be connected to different word lines WL1 to WLm, respectively.

In this structure, writing and reading may be performed in units of rows of memory cell strings CS11 to CSkn. For example, the memory cell strings CS11 to CSkn may be selected as a unit of rows by the common source lines CSLs, and the memory cell strings CS11 to CSkn may be selected as a unit of rows by the string selection lines SSLs. Also, in a selected row of the memory cell strings CS11 to CSkn, writing and reading may be performed in units of pages. For example, a page may be a single row of memory cells MC connected to one word line WL. In a selected row of the memory cell strings CS11 to CSkn, the memory cells MC may be selected as units of pages by the word lines WL.

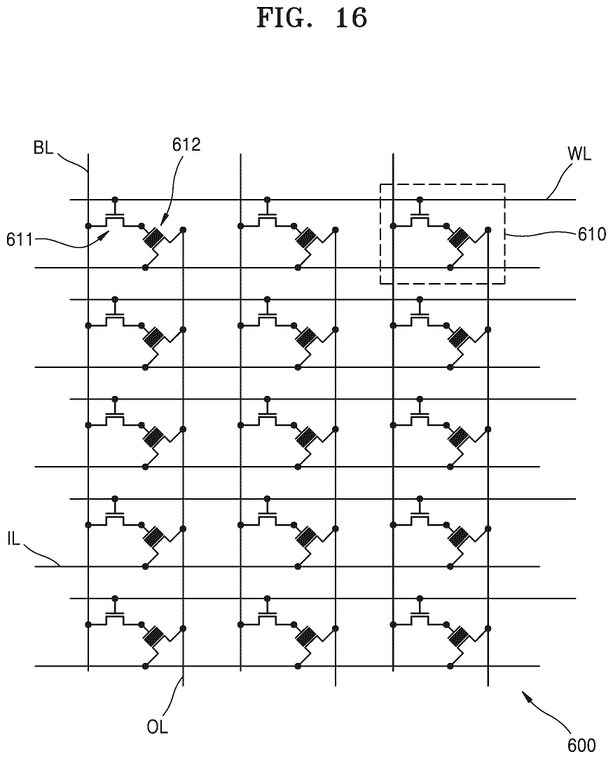

FIG. 16 is a schematic circuit diagram of a neural network device according to an example embodiment.

Referring to FIG. 16, a neural network device 600 according to an example embodiment may include an array of a plurality of synaptic elements 610, which are two-dimensionally arranged. Each of the plurality of synaptic elements 610 may include an access transistor 611 and a FeFET 612. The FeFET 612 may be any one of the FeFETs described with reference to FIGS. 10, 11, and 14. The access transistor 611 may serve as a selection device that turns on/off the synaptic element 610.

The neural network device 600 may also include a plurality of word lines WL, a plurality of bit lines BL, a plurality of input lines IL, and a plurality of output lines OL. A gate of the access transistor 611 may be electrically connected to any one of the plurality of word lines WL, a source thereof may be electrically connected to any one of the plurality of bit lines BL, and a drain thereof may be connected to a gate of the FeFET 612. In addition, a source of the FeFET 612 may be electrically connected to any one of the plurality of input lines IL, and a drain thereof may be electrically connected to any one of the plurality of output lines OL.

During a training operation of the neural network device 600, the access transistor 611 may be individually turned on through an individual word line WL, and a program pulse may be applied to the gate of the FeFET 612 through the bit line BL. A signal of training data may be applied through the input line IL. Through this process, weight may be stored in each FeFET 612.

When the neural network device 600 performs an inference operation, all access transistors 611 may be turned on through all word lines WL, and a read voltage (Vread) may be applied through the bit line BL. Then, current from the synaptic elements 610 connected in parallel to the output line OL may be summed up and flow to each output line OL. As the plurality of output lines OL are connected to output circuits, current flowing through each output line OL may be converted into a digital signal.

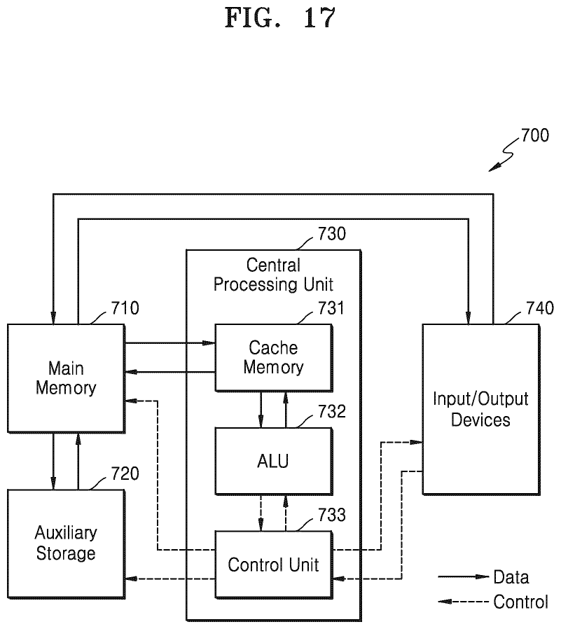

The semiconductor device 100 according to an example embodiment may be used for data storage in various electronic apparatuses. FIG. 17 is a conceptual diagram schematically illustrating a device architecture that may be applied to an electronic apparatus according to an example embodiment. Referring to FIG. 17, an electronic apparatus 700 may include main memory 710, an auxiliary storage 720, a central processing unit (CPU) 730, and an input/output device 740. The CPU 730 may include cache memory 731, an arithmetic logic unit (ALU) 732, and a control unit 733. The cache memory 731 may include static random-access memory (SRAM). The main memory 710 may include a DRAM device, and the auxiliary storage 720 may include at least one of the semiconductor device 100 and the FeFETs 200, 300, 400, and 500 according to an example embodiment. in some example embodiments, the cache memory 731, the main memory 710, and the auxiliary storage 720 may all include at least one of the semiconductor device 100 and the FeFETs 200, 300, 400, and 500 according to an example embodiment. In some cases, the electronic apparatus 700 may be implemented in a form in which computing unit elements and memory unit elements are adjacent to each other in a single chip, without distinction of the above sub-units.

Some of the elements and/or functional blocks disclosed above may be implemented as processing circuitry, such as hardware including a logic circuit, a hardware/software combination, such as processor execution software, or a combination thereof. For example, the processing circuitry may include a CPU, an ALU, a digital signal processor, a microcomputer, a field programmable gate array (FPGA), a system-on-chip (SoC), a programmable logic unit, a microprocessor, an application-specific integrated circuit (ASIC), or the like. The processing circuitry may include electronic components, such as at least one of a transistor, a resistor, a capacitor, or the like. The processing circuitry may include electronic components, such as at least one logic gate from among an AND gate, an OR gate, a NAND gate, a NOR gate, or the like.

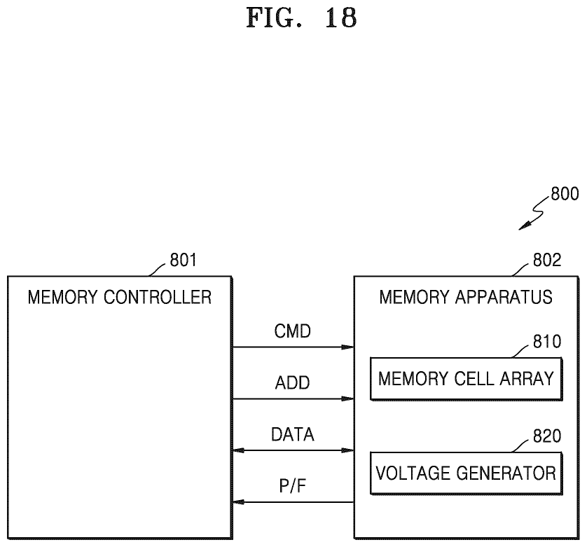

FIG. 18 is a block diagram of a memory system 800 according to an example embodiment.

Referring to FIG. 18, the memory system 800 may include a memory controller 801 and a memory apparatus 802. The memory controller 801 performs a control operation on the memory apparatus 802, and for example, the memory controller 801 provides, to the memory apparatus 802, an address ADD and a command CMD to perform a programming (or writing), reading, and/or erasing operation on the memory apparatus 802. In addition, data for a programming operation and reading may be transmitted between the memory controller 801 and the memory apparatus 802.

The memory apparatus 802 may include a memory cell array 810 and a voltage generator 820. The memory cell array 810 may include a plurality of memory cells, and may include at least one of the semiconductor device 100 and the FeFETs 200, 300, 400, and 500 according to the example embodiment described above.

The memory controller 801 may include processing circuitry, such as hardware including a logic circuit, a hardware/software combination, such as a processor execution software, or a combination thereof. For example, the processing circuitry may include a CPU, an ALU, a digital signal processor, an FPGA, an SoC, a programmable logic unit, a microprocessor, an ASIC, or the like, but is not limited thereto. The memory controller 801 may be configured to operate in response to a request from a host (not shown), access the memory apparatus 802, and control the control operations (e.g., write/read operations) described above, thereby transforming the memory controller 801 into a special-purpose controller. The memory controller 801 may generate the address ADD and the command CMD to perform programming/read/erase operations on the memory cell array 810. In addition, in response to a command from the memory controller 801, the voltage generator 820 may generate a voltage control signal to control a voltage level of a word line for data programming or data reading in the memory cell array 810.

In addition, the memory controller 801 may perform a determination operation on data read from the memory apparatus 802. For example, the number of on-cells and/or the number of off-cells may be determined from data read from a memory cell. The memory device 802 may provide a pass/fail signal P/F to the memory controller 801 according to a read result for the read data. The memory controller 801 may control write and read operations of the memory cell array 810 by referring to the pass/fail signal P/F.

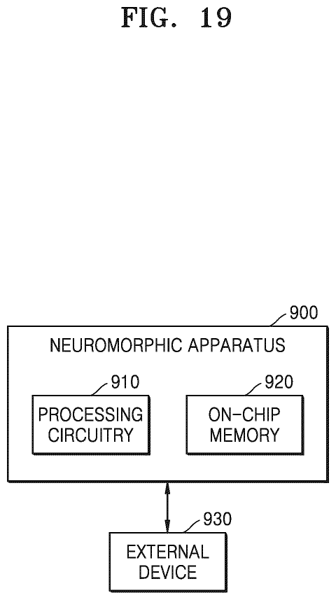

FIG. 19 is a block diagram of a neuromorphic apparatus 900 according to an example embodiment and an external device connected to the neuromorphic device 900.

Referring to FIG. 19, the neuromorphic device 900 may include processing circuitry 910 and/or on-chip memory 920. The on-chip memory 920 may include at least one of the semiconductor device 100 and the FeFETs 200, 300, 400, and 500 according to the example embodiments described above.

In some example embodiments, the processing circuitry 910 may be configured to control a function to drive the neuromorphic device 900. For example, the processing circuitry 910 may be configured to control the neuromorphic device 900 by executing a program stored in the on-chip memory 920. In some example embodiments, the processing circuitry 910 may include hardware such as a logic circuit, a hardware/software combination such as a processor executing software, or a combination thereof. For example, the processor may include a CPU, a graphics processing unit (GPU), an application processor (AP) included in the neuromorphic apparatus 900, an ALU, a digital signal processor, a microcomputer, an FPGA, an SoC, a programmable logic unit, a microprocessor, an ASIC, or the like, but is not limited thereto. In some example embodiments, the processing circuitry 910 may be configured to write/read various pieces of data to/from an external device 930 and/or execute the neuromorphic device 900 by using the read/written data. In some example embodiments, the external device 930 may include an external memory and/or sensor array having an image sensor (e.g., a complementary metal oxide semiconductor (CMOS) image sensor circuit).

In some example embodiments, the neuromorphic device 900 may be applied to a machine learning system. The machine learning system may use a variety of artificial neural network organization and processing models, such as a convolutional neural network (CNN), a deconvolutional neural network, a recurrent neural network(RNN) selectively including a long short-term memory (LSTM) unit and/or a gated recurrent unit (GRU), a stacked neural network (SNN), a state-space dynamic neural network (SSDNN), a deep faith network (DBN), a generative adversarial network (GAN), and/or a restricted Boltzmann machine (RBM).

In some example embodiments or additionally, such a machine learning system may include combinations of other forms of machine learning models, such as linear and/or logistic regression, statistical clustering, Bayesian classification, decision trees, dimensionality reduction such as principal component analysis, expert systems, and/or ensembles such as random forests. Such a machine learning machine may be used to provide various services and/or applications, for example, an image classification service, a user authentication service based on biometric information or biometric data, an advanced drive assistance system (ADAS) service, a voice assistance service, an automatic speech recognition (ASR) service, or the like, which may be executed by an electronic apparatus.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

A semiconductor device according to an example embodiment may improve SS by including an interface region in a ferroelectric layer. The ferroelectric layer may improve SS by reducing interface deterioration by including the interface region at an interface with a channel layer.

A method of manufacturing a semiconductor device, according to an example embodiment, may include forming an interface region at an interface between a ferroelectric layer and a channel layer.

It should be understood that the example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer comprising an oxide semiconductor;
a ferroelectric layer on the channel layer; and
a gate electrode on the ferroelectric layer,
wherein the ferroelectric layer comprises an interface region, the interface region being a local region of the ferroelectric layer from an interface between the ferroelectric layer and the channel layer to a distance of 15 % or less of a thickness of the ferroelectric layer,
the interface region comprises a first material, a second material, and oxygen,
the first material comprises at least one of Mo, TiN, W, or ITO, and
the second material comprises at least one of Al, Ti, or Ta.

2. The semiconductor device of claim 1, wherein a peak of a content profile of the second material in the interface region is within a distance range of 15 % or less of the thickness of the ferroelectric layer from the interface between the channel layer and the ferroelectric layer.

3. The semiconductor device of claim 2, wherein a content peak of the second material is greater than 0 and 25 at % or less.

4. The semiconductor device of claim 2, wherein a content peak of the first material is greater than 0 and 0.5 at % or less.

5. The semiconductor device of claim 1, wherein a content ratio of the second material to the first material in the interface region is about 1 or more and about or less.

6. The semiconductor device of claim 1, wherein the first material and the second material are dispersed in the interface region.

7. The semiconductor device of claim 1, wherein
the channel layer, the ferroelectric layer, and the gate electrode are arranged in a concentric shape,
the ferroelectric layer comprises the interface region at a region adjacent to the channel layer, and
the gate electrode surrounds the ferroelectric layer.

8. The semiconductor device of claim 7, wherein
the gate electrode comprises a plurality of gate electrodes,
the plurality of gate electrodes are arranged to be spaced apart from each other in a first direction, and
a spacer is arranged between each pair of the plurality of gate electrodes.

9. An electronic apparatus comprising an array of a plurality of synaptic elements two-dimensionally arranged, wherein
any one or more of the plurality of synaptic elements comprise an access transistor and a ferroelectric field-effect transistor,
the ferroelectric field-effect transistor comprises
a channel layer comprising an oxide semiconductor,
a ferroelectric layer on the channel layer, and
a gate electrode on the ferroelectric layer,
the ferroelectric layer comprises an interface region, the interface region being a local region of the ferroelectric layer from an interface between the ferroelectric layer and the channel layer to a distance of 15 % or less of a thickness of the ferroelectric layer,
the interface region comprises a first material, a second material, and oxygen,
the first material comprises at least one of Mo, TiN, W, or ITO, and
the second material comprises at least one of Al, Ti, or Ta.

10. The electronic apparatus of claim 9, wherein a peak of a content profile of the second material in the interface region is within a distance range of 15 % or less of the thickness of the ferroelectric layer from the interface between the channel layer and the ferroelectric layer.

11. The electronic apparatus of claim 9, wherein a content peak of the second material is greater than 0 and 25 at % or less.

12. The electronic apparatus of claim 9, wherein a content peak of the first material is greater than 0 and 0.5 at % or less.

13. A method of manufacturing a semiconductor device, the method comprising:
forming a ferroelectric precursor layer;
forming a ferroelectric layer by crystallizing the ferroelectric precursor layer by using a first material;
forming an interface region within the ferroelectric layer by depositing a second material different from the first material on the ferroelectric layer using an atomic layer deposition method; and
forming an oxide semiconductor channel layer on the interface region,
wherein the first material comprises at least one of Mo, TiN, W, or ITO, and
the second material comprises at least one of Al, Ti, or Ta.

14. The method of claim 13, wherein the interface region is provided within a distance range of 15 % or less of a thickness of the ferroelectric layer from an interface between the oxide semiconductor channel layer and the ferroelectric layer.

15. The method of claim 14, wherein a peak of a content profile of the second material in the interface region is within a distance range of 15 % or less of the thickness of the ferroelectric layer from the interface between the oxide semiconductor channel layer and the ferroelectric layer.

16. The method of claim 13, wherein the forming of the ferroelectric layer comprises forming a layer of the first material on the ferroelectric precursor layer and crystallizing the ferroelectric precursor layer through heat treatment.

17. The method of claim 16, further comprising:
removing the layer of the first material after crystallizing the ferroelectric precursor layer.

18. The method of claim 17, wherein at least some of the first material remains after performing the removing of the layer of the first material.

19. The method of claim 13, wherein the depositing of the second material by the atomic layer deposition method is performed in a range of cycles of 1 or more and 20 or less.
